(19) United States
(12) Patent Application Publication
(10) Pub. No.: US 2005/0072834 A1
(43) Pub. Date: Apr. 7, 2005

(54) Connection site coating method and solder joints

(76) Inventor: Kejun Zeng, Coppell, TX (US)

Correspondence Address: TEXAS INSTRUMENTS INCORPORATED, P O BOX 655474, M/S 3999, DALLAS, TX, 75265, US

(21) Appl. No.: 10/679,787

(22) Filed: Oct. 6, 2003

(51) Int. Cl. B23K 31/02

(52) U.S. Cl. 228/180.22; 228/246

(57) ABSTRACT

Disclosed are methods and apparatus forming a solder joint (18) for electronic components and PCB assembly (10). Disclosed representative embodiments of the methods and resulting apparatus include a circuit board (PCB or component substrate) (12) having at least one connection site (14) for leaded or leadless components also having connection sites, to which a nickel diffusion barrier (20) and copper wetting layer (22) are applied to within selected thicknesses. Solder (16) is positioned on the prepared connection site (14) and a solder joint (18) is formed by reflowing the solder (16), promoting the formation of Cu₆Sn₅ (18).

### TECHNICAL FIELD

The invention relates to electronics and electronics manufacturing. More particularly, the invention relates to methods for coating connection sites and forming solder joints in electronic components and printed circuit board assemblies.

### BACKGROUND OF THE INVENTION

Connections among discrete semiconductor devices on a printed circuit board (PCB) or other substrate are frequently made using solder joints. For example in a BGA assembly process, solder nodules or “balls” having spherical, near-spherical, or other shapes are positioned at prepared metallized locations on a workpiece such as a PCB or semiconductor device. The workpiece is then heated, typically to about 220° C. or more, to reflow the solder balls. Upon cooling, the solder balls bond with the metallized locations. A semiconductor package or circuit board having a corresponding pattern of metallized connection sites may be aligned with the BGA and bonded to it by controlled heating.

Numerous techniques have been developed for aligning, positioning, retaining, and attaching solder on connection sites on a workpiece. Despite the various approaches, problems still arise in the formation of a robust solder joint between the solder and the metallized connection site. Electronic devices, including both components and PCB assembly, are increasingly required to withstand high temperature storage, thermal cycling, temperature shock, and mechanical shocks. On the one hand, some manufacturing techniques provide solder joints exhibiting adequate performance in thermal tests, but poor performance in drop tests. On the other hand, some manufacturing techniques provide solder joints that perform adequately in drop tests, but are inadequate in the thermal tests such as high temperature storage, thermal cycling, temperature shock. Due to these and other problems, methods and apparatus providing solder joints resistant to both thermal and mechanical stresses would be useful and advantageous in the arts.

### SUMMARY OF THE INVENTION

In carrying out the principles of the present invention, in accordance with preferred embodiments thereof, the invention provides solder joints for electronic devices (both components and PCB assembly) that are able to withstand both thermal (high temperature storage, thermal cycling, temperature shock) and mechanical stresses, such as drop testing. The methods and apparatus of the invention provide advantages over the prior art including but not limited to improvements in strength, range of operating conditions, and reliability.

According to one aspect of the invention, a method for forming a solder joint on a copper pad or connection site is described. The method includes steps for applying a nickel layer to the copper connection site and applying a copper layer to the nickel layer. Solder is subsequently positioned on the copper layer. Reflowing the solder forms the solder joint.

According to one aspect of the invention, a copper layer is applied to a diffusion barrier on a bond pad or connection site. The copper layer has a thickness within the range of approximately 0.6 micron to approximately 6 microns.

According to a further aspect of the invention, a nickel layer is applied to a bond pad or connection site with a thickness within the range of approximately 1 micron to approximately 5 microns.

According to another aspect of the invention, steps include forming a bond of Cu₆Sn₅ between a copper layer on a bond pad or connection site and solder.

According to yet another aspect of the invention, a preferred embodiment is described in which a solder joint has a copper pad or connection site with metallized coatings. On the pad or connection site, a copper wetting surface is backed by a nickel diffusion barrier. Solder is bonded to the copper wetting surface.

According to a further aspect of the invention, the copper wetting surface is within a range of between approximately 0.6 micron and approximately 6 microns in thickness.

According to an additional aspect of the invention, the nickel diffusion barrier is within a range of between approximately 1 micron and approximately 5 microns in thickness.

According to an aspect of the invention, the junction of solder with a bond pad or connection site is formed of Cu₆Sn₅.

An example of a preferred embodiment is disclosed in which the invention is used to form solder joints on a ball grid array (BGA).

The invention provides technical advantages including but not limited to manufacturing solder joints endowed with the capability of withstanding both thermal tests and drop tests. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings of exemplary embodiments in which:

FIG. 1 is a top perspective view of a circuit board (PCB or component substrate) showing an example of a preferred embodiment of the invention;

FIG. 2A is a cut-away partial side view of a portion of a circuit board (PCB or component substrate) including a bond pad illustrating an example of methods and apparatus embodying the invention; and

FIG. 2B is a cut-away partial side view of a portion of a circuit board (PCB or component substrate) including a bond pad further illustrating an example of methods and apparatus embodying the invention.

References in the detailed description correspond to the references in the figures unless otherwise noted. Descriptive and directional terms used in the written description such as first, second, left, right, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

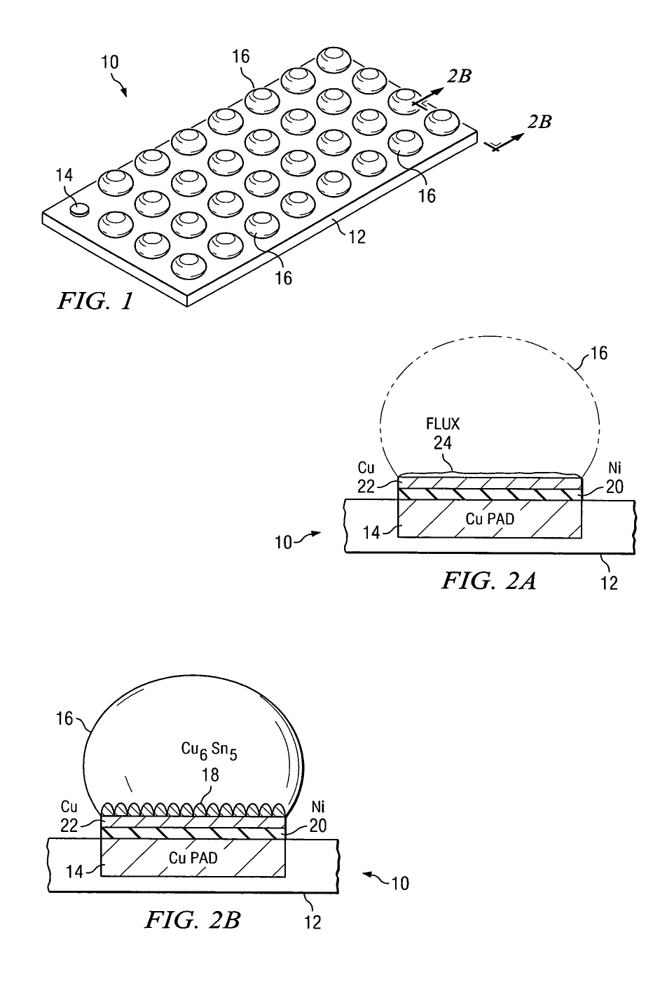

In general, the invention provides robust and durable solder joints using a diffusion barrier of nickel and copper wetting surface atop a copper bond pad or connection site. A view of an electronic circuit board (PCB or component substrate) assembly 10 embodying an example of the invention in a typical application is presented in FIG. 1. A circuit board (PCB or component substrate) 12 has an array of bond pads 14 on the board 12 with solder balls 16 attached. It should be appreciated that the invention may be used with various semiconductor package configurations, for example, PCB, BGA, CSP, flip-chip, leadless or leaded components, QFP and QFN.

Referring primarily to FIG. 2A, a partial cut-away view of a solder joint 18 and the steps for forming the same are shown and described. A circuit board 12 or other supporting structure is prepared with metallic bond pads 14 as familiar in the arts. A nickel layer 20 is attached to the bond pad 14, preferably using an electrolytic plating process as known in the arts. Atop the nickel layer 20, a copper layer 22 is applied, preferably also by electrolytic plating. Alternatively, electroless plating may also be used for applying the copper and nickel layers 20, 22. Subsequently, a solder ball 16 is positioned atop the copper layer 22. It should be appreciated that although nominally a “ball,” the solder ball 16 need not be spherical in shape. In general, for some types of components such as leaded components, the solder balls are not spherical. Typically, in an intermediate step a flux material 24 may be applied to promote bonding of the solder ball 16 onto the copper layer 22.

The steps shown and described with respect to FIG. 2A are performed preparatory to controlled heating to reflow the solder 16. Now referring primarily to FIG. 2B, a partial cut-away view taken along line 2B-2B of FIG. 1 illustrates a bond pad 14 with a solder joint 18 using the invention. Upon reflow of the solder ball 16 and subsequent cooling, a bond 18 is formed between the solder ball 16 and the copper layer 22. The copper layer 22 performs as a wetting layer providing a bonding surface for the molten solder upon reflow of the solder ball 16. The underlying nickel layer 20 functions as a barrier to arrest diffusion of copper 22 from above. It has been determined that it is preferable to form the nickel 20 and copper 22 layers specified within a particular range of thicknesses in order to promote the formation of a strong and durable bond 18 of Cu₆Sn₅ on the copper layer 22.

The use of the nickel and copper layers 20, 22 in the appropriate thicknesses provides sufficient wetting surface 22 backed up by a diffusion barrier 20 to promote bond 18 formation while reducing the formation of Kirkendall voids in the junction 18 of the copper 22. It has been determined that a copper layer 22 less than about 0.6 micron in thickness does not provide sufficient copper for the least number of reflows. A copper layer 22 thickness in excess of about 6 microns, however, provides abundant copper to diffuse through the intermetallic compounds formed at the interface of the solder joint, forming a great amount of Kirkendall voids and thus resulting in a weak bond. It has also been determined that a nickel layer 20 of less than about 1 micron thickness does not provide a sufficient diffusion barrier, again permitting the formation of excessive voids, while a thickness of greater than about 5 microns of nickel brings too much stress to the interface. The thicknesses of the nickel and copper layers, 20, 22 may be varied within the specified ranges without departure from the principles of the invention. For example, for some applications where either mechanical stresses or temperature concerns are foremost, the relative thicknesses of the layers, 20, 22 may be adjusted accordingly within their respective ranges in order to provide solder joints 18 with the desired characteristics.

Thus, the invention provides strong, mechanically and thermally reliable, solder joints for use in electronic components as well as PCB assembly. While the invention has been described with reference to certain illustrative embodiments, the methods and apparatus described are not intended to be construed in a limiting sense. Various modifications and combinations of the illustrative embodiments as well as other advantages and embodiments of the invention will be apparent to persons skilled in the art upon reference to the description and claims.

1. A method for forming a solder joint in electronic assemblies having one or more copper bond connection sites, the method comprising the steps of:
applying a nickel layer to at least one copper connection site;
applying a copper layer to the nickel layer;
applying a solder ball to the copper layer;
reflowing the solder thereby forming a solder joint.

2. A method according to claim 1 further comprising a step of applying a flux material to the copper layer prior to applying the solder ball.

3. A method according to claim 1 wherein the nickel layer is applied to a thickness of greater than about 1 micron.

4. A method according to claim 1 wherein the nickel layer is applied to a thickness of less than about 5 microns.

5. A method according to claim 1 wherein the nickel layer is applied to a thickness within the range of approximately 1 micron to approximately 5 microns.

6. A method according to claim 1 wherein the copper layer is applied to a thickness of greater than about 0.6 micron.

7. A method according to claim 1 wherein the copper layer is applied to a thickness of less than about 6 microns.

8. A method according to claim 1 wherein the copper layer is applied to a thickness within the range of approximately 0.6 micron to approximately 6 microns.

9. A method according to claim 1 wherein the step of applying the nickel further comprises both electrolytic and electroless plating.

10. A method according to claim 1 wherein the step of applying the copper layer further comprises both electrolytic and electroless plating.

11. A method according to claim 1 wherein the step of reflowing the solder further comprises the formation of Cu₆Sn₅ for forming a bond between the copper layer and the solder.

12. A solder joint for a semiconductor apparatus assembly, wherein the assembly has at least one copper connection site, the solder joint comprising:
a nickel layer on at least one copper connection site;
a copper layer atop the at least one nickel layer; and
a solder ball coupled to the copper layer forming a bond.

13. A solder joint according to claim 12 wherein the bond comprises Cu₆Sn₅.

14. A solder joint according to claim 12 wherein the nickel layer comprises nickel having a thickness of greater than about 1 micron.

15. A solder joint according to claim 12 wherein the nickel layer comprises nickel having a thickness of less than about 5 microns.

16. A solder joint according to claim 12 wherein the nickel layer comprises nickel having a thickness within a range of between approximately 1 micron and approximately 5 microns.

17. A solder joint according to claim 12 wherein the copper layer comprises copper having a thickness of greater than about 0.6 micron.

18. A solder joint according to claim 12 wherein the copper layer comprises copper having a thickness of less than about 6 microns.

19. A solder joint according to claim 12 wherein the copper layer comprises copper having a thickness within a range of between approximately 0.6 micron and approximately 6 microns.

20. A BGA comprising:
a board having a plurality of metallized connection sites;
a nickel layer on a plurality of the metallized connection sites;
a copper layer atop a plurality of the nickel layers; and
a solder ball coupled to the copper layer forming a bond.

21. A BGA according to claim 20 wherein the bond comprises Cu₆Sn₅.

22. A BGA according to claim 20 wherein the nickel layer comprises nickel having a thickness of greater than about 1 micron.

23. A BGA according to claim 20 wherein the nickel layer comprises nickel having a thickness of less than about 5 microns.

24. A BGA according to claim 20 wherein the nickel layer comprises nickel having a thickness within a range of between approximately 1 micron and approximately 5 microns.

25. A BGA according to claim 20 wherein the copper layer comprises copper having a thickness of greater than about 0.6 micron.

26. A BGA according to claim 20 wherein the copper layer comprises copper having a thickness of less than about 6 microns.

27. A BGA according to claim 20 wherein the copper layer comprises copper having a thickness within a range of between approximately 0.6 micron and approximately 6 microns.
